(19) United States
(12) Patent Application Publication
(10) Pub. No.: US 2016/0373108 A1
(43) Pub. Date: Dec. 22, 2016

(54) MULTIPLEXOR LOGIC FUNCTIONS IMPLEMENTED WITH CIRCUITS HAVING TUNNELING FIELD EFFECT TRANSISTORS (TFETS)

(71) Applicant: INTEL CORPORATION, Santa Clara, CA (US)

(72) Inventors: Daniel H. MORRIS, Hillsboro, OR (US); Uygar E. AVCI, Portland, OR (US); Rafael RIOS, Portland, OR (US); Ian A. YOUNG, Portland, OR (US)

(73) Assignee: Intel Corporation, Santa Clara, CA (US)

(21) Appl. No.: 15/122,150

(22) PCT Filed: Mar. 27, 2014
(86) PCT No.: PCT/US2014/032019

§ 371 Date: Aug. 26, 2016

(51) Int. Cl. H03K 17/693; H01L 29/775; G11C 5/06; H01L 27/092

(52) U.S. Cl. CPC H03K 17/693; H01L 27/092; H01L 29/775; G11C 5/066

(57) ABSTRACT

Multiplexor circuits with Tunneling field effect transistors (TFET) devices are described. For example, a multiplexor circuit includes a first set of tunneling field effect transistor (TFET) devices that are coupled to each other. The first set of TFET devices receive a first data input signal, a first select signal, and a second select signal. A second set of TFET devices are coupled to each other and receive a second data input signal, the first select signal, and the second select signal. An output terminal is coupled to the first and second set of TFETs. The output terminal generates an output signal of the multiplexor circuit.

### TECHNICAL FIELD

Embodiments of the invention are in the field of semiconductor devices and, in particular, multiplexor logic functions that are implemented with circuits having tunneling field effect transistors (TFETs).

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, leading to the fabrication of products with increased memory capacity. The drive for ever-more capacity, however, is not without issue. The necessity to optimize the power and performance of each device becomes increasingly significant.

In the manufacture of integrated circuit devices, a metal oxide semiconductor field effect transistors (MOSFETs) can be used for multiplexor logic functions and implemented with pass gate multiplexor circuits and tri-state multiplexor circuits. However, the MOSFETs have a symmetrical current-voltage characteristics with undesirable leakage current during certain drain to source voltage biasing conditions.

### BRIEF DESCRIPTION OF THE DRAWINGS

FIG. 1a illustrates current voltage characteristics for a MOSFET device for a conventional approach;

FIG. 1b illustrates current voltage characteristics for a TFET device in accordance with one embodiment;

FIG. 2 illustrates a diagram of a multiplexor logic gate;

FIG. 3 illustrates a block diagram of a multiplexor circuit 300 having TFET devices in one embodiment;

FIG. 4a illustrates a pass gate MUX circuit with TFET devices and an inverter in accordance with one embodiment;

FIG. 4b illustrates a tri-state gate MUX circuit with TFET devices and an inverter in accordance with one embodiment;

FIG. 5 illustrates a tri-state-like TFET multiplexor circuit in accordance with one embodiment;

FIG. 6 illustrates a multiplexor circuit having TFET devices in accordance with one embodiment;

FIG. 7 illustrates a multiplexor circuit having MOSFET devices;

FIG. 8 illustrates a multiplexor circuit having TFET devices in accordance with one embodiment;

FIG. 9 illustrates a multiplexor circuit having TFET devices in accordance with one embodiment;

FIG. 10 illustrates a multiplexor circuit having TFET devices in accordance with one embodiment;

FIGS. 11A-11C illustrate layouts of a TFET MUX circuit in accordance with one embodiment.

FIG. 12 illustrates a computing device in accordance with one implementation of the invention.

### DESCRIPTION OF THE EMBODIMENTS

Multiplexor logic functions implemented with circuits having Tunneling field effect transistors (TFETs) are described. In the following description, numerous specific details are set forth, such as specific integration and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

Generally, embodiments described herein may be suitable for high performance or scaled transistors for dense logic devices having low power applications. A multiplexor based circuit (e.g., multiplexor, demultiplexor, adder, XOR, flip-flop, etc.) includes tunneling field effect transistor (TFET) devices and utilizes the TFET's unique symmetric current voltage characteristics.

In one embodiment, a multiplexor based circuit includes a first set of tunneling field effect transistor (TFET) devices that are coupled to each other. The first set of TFET devices receive a first data input signal, a first select signal, and a second select signal. A second set of TFET devices are coupled to each other and receive a second data input signal, the first select signal, and the second select signal. An output terminal is coupled to the first and second set of TFETs. The output terminal generates an output signal of the multiplexor circuit. The first set of TFET devices is coupled to the second set of TFET devices with a connection that provides the second select signal.

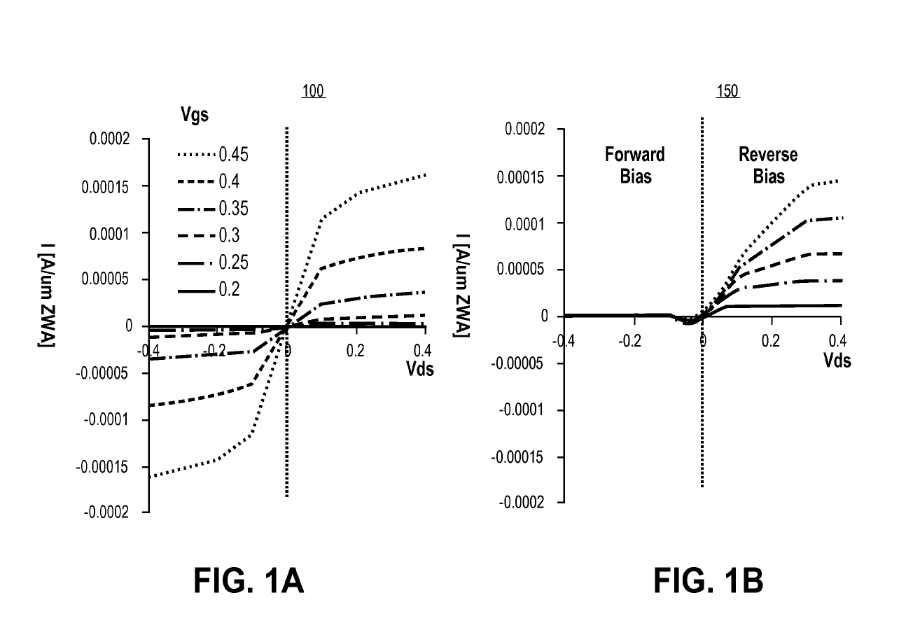

FIG. 1a illustrates a diagram with current voltage characteristics for a MOSFET device for a conventional approach. The diagram 100 shows a voltage applied from drain to source (V_{DS}) on a horizontal axis versus a current from drain to source (I_{Ds}) on a vertical axis for different gate to source voltage biasing. A positive and negative V_{DS} both cause current conduction with sufficient gate to source voltage biasing. In other words, the MOSFET device has symmetric current voltage characteristics.

FIG. 1b illustrates current voltage characteristics for a TFET device in accordance with one embodiment. A TFET can conduct substantial high currents for positive drain-source bias, and conducts non-substantial low currents (e.g., 1 nA or less) for negative drain-source bias. This unidirectional conduction can be used for a dense multiplexor (MUX) implementation by combining logic gates conventionally implemented with separate pull-up and pull-down MOSFET circuits into a single shared circuit. With MOSFET devices, this arrangement of devices in a single shared circuit would cause short circuit currents, excessive power consumption and loss of functionality. However for TFET devices, this arrangement of devices has improved area, timing, and power in comparison to MOSFET MUX designs. The two principle types of MUX circuits are the pass gate MUX and the tri-state MUX. The novel compact TFET MUX circuit design disclosed herein provides improvements in power, performance and area compared to MOSFET MUX designs. Most significantly, in one embodiment, there are also two fewer transistors in the compact TFET MUX design resulting in the potential for 20% reduction in transistor width.

In addition to pass gate and tri-state MUXes, other MUX topologies are enhanced with TFETs in comparison to MOSFET MUX topologies. However, these other MUX topologies may not generally be appropriate for logic in advanced semiconductor technologies because these other MUX topologies may use clocked signals, ratioed devices or non-regenerative transfer characteristics resulting in excessive dynamic power, static power or sensitivity to variation.

TFET devices have oppositely doped source and drain regions. For example, a GaSb—InAs Heterojunction n-type TFET (NTFET) uses a P+ source region, undoped channel region, and N+ drain region. As a result, the source and the drain terminals are not interchangeable and the current voltage (IV) characteristic is asymmetric. For an NTFET, the current from drain to source region (I_{Ds}) is modulated between high and low values by a gate voltage (V_{GS}) when V_{GS} and V_{DS} are positive. However, when V_{DS} is less than zero i.e. negative (but more negative than a turn-on voltage) then I_{DS} is orders of magnitude below its maximum I_{DS} saturation value. As a result, the TFET device can strongly conduct in one direction for a positive V_{DS}, which is actually a reverse bias of the lateral p-n source to drain intrinsic diode, but not conduct in the other direction for a negative V_{DS}, which is actually a forward bias of the lateral p-n source to drain intrinsic diode, as illustrated in FIG. 1b.

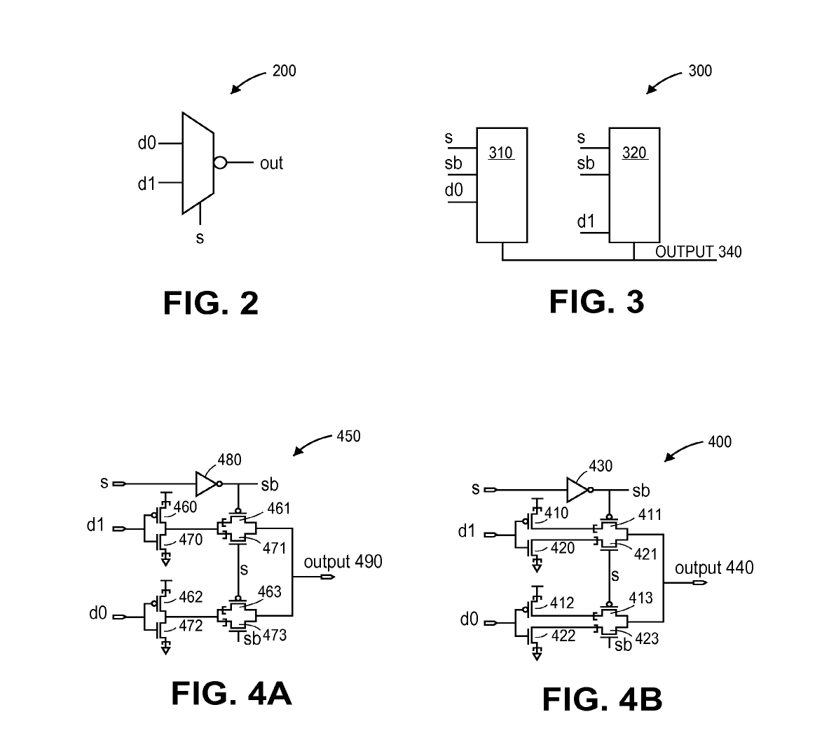

A diagram of a MUX logic gate is shown in FIG. 2. The primary inputs to the gate are “s” (a first select signal), “d0” (a first data input signal), and “d1” (a second data input signal). The primary output is labeled “out”. The logical value of the select signal “s” multiplexes one of the input data values to the output. The logic gates are inverting so the output is in fact the complement of the selected input. An inverter could be connected on the output as well to provide a non-inverted version of the output signal. The “sb” (a second select signal) is not labeled in FIG. 2 because it is a signal internal to the logic gate. The select signal “sb” is the inverse of the select signal “s” and is necessary to drive the gate of N and P transistors that select or deselect the output.

FIG. 3 illustrates a block diagram of a multiplexor circuit 300 having TFET devices in one embodiment. A first set of tunneling field effect transistor (TFET) devices 310 (e.g., at least two NTFETs, at least two PTFETS) are coupled to each other. The TFET devices 310 receive at least a first data input signal “d0”, a first select signal “s”, and a second select signal “sb”. Additional select and data input signals may also be received for other MUX designs (e.g., a multiplexer of 2ⁿ inputs has n select lines). A second set of TFET devices (e.g., at least two NTFETs, at least two PTFETS) are coupled to each other. These devices receive a second data input signal “d1”, the first select signal “s”, and the second select signal “sb”. Additional select and data input signals may also be received. An output terminal 340 (“out” in FIG. 2) is coupled to the first and second set of TFET devices. The output terminal generates an output signal of the multiplexor circuit 300.

The first set of TFET devices may be coupled to the second set of TFET devices with a connection that provides the second select signal “sb” to the second set of TFET devices (e.g., connection 650, connection 850, connection 950, connection 1050). In one embodiment, the first set of TFETs are serially connected to each other (i.e., the source and drain terminals are serially connected to each other). The gate terminals are connected in a different manner. Each TFET of the first set of TFETs receives one of the first data input signal, the first select signal, and the second select signal respectively. The first set of TFETs includes at least two n-type TFETs and at least two p-type TFETs. The TFETs of the second set of TFETs are serially connected to each other (i.e., the source and drain terminals are serially connected to each other). Each TFET of the second set of TFETs receives one of the second data input signal, the first select signal, and the second select signal. The second set of TFETs includes at least two n-type TFETs and at least two p-type TFETs. In one embodiment, the multiplexor circuit 300 includes a maximum of eight TFETs. In another embodiment, FIG. 3 includes an inverter (e.g., 480, 430, 530) for generating the signal “sb” from the signal “s”. FIG. 4a illustrates a pass gate MUX circuit with TFET devices and an inverter in accordance with one embodiment. The circuit 450 includes PTFET devices 460-463, NTFET devices 470-473, an inverter 480, and an output 490. FIG. 4b illustrates a tri-state gate MUX circuit with TFET devices and an inverter in accordance with one embodiment. The circuit 400 includes PTFET devices 410-413, NTFET devices 420-423, an inverter 430, and an output 440. The topologies shown in these figures are preferred for MOSFET devices used in MUX circuits. In the figures with TFET devices, the source terminal is indicated by a bracket-like shape. Appropriate orientation of the source and drain is essential for circuit to be functioning correctly. Circuit simulations have verified the functionality of these circuits and performance summarized in Table 1 below.

| | | Avg. | | | |
|---|---|---|---|---|---|
| | | Delay | | | |
| | | [ps] | Avg. | Mean | Total |
| | Supply | (inc. 3 | E_{DYN} | Leakage | Z |
| MUX Circuit | Voltage | stages) | [aJ] | [pA] | [DG] |
| CMOS Pass Gate | 0.45 | 82 | 49 | 283 | 10 |
| TFET Pass Gate | 0.35 | 82 | 22 | 200 | 10 |
| CMOS Tri-State | 0.45 | 87 | 44 | 144 | 10 |
| TFET Tri-State | 0.35 | 81 | 21 | 133 | 10 |
| CMOS Compact | This topology is not functional for MOSFET | | | | |
| TFET MUX | 0.35 | 80 | 20 | 125 | 8 |
| Compact | | | | | |

For this comparison, the TFET and CMOS devices are designed to have equal leakage and inverter performance and their respective supply voltages are 450 mV for CMOS and 350 mV for TFET. The reported delay is averaged across all possible transitions between logic values on the input and output. The delay value includes the propagation time through input and output inverters in addition to the MUX itself in order to fully comprehend differences in MUX input capacitance and drive strength. The compact TFET MUX topology is faster than the alternatives. The leakage of the gate is lower because of the reduction of leakage paths in the new TFET MUX design. The TFET MUX compact design also has a lower switching energy (average Edyn [aJ]) compared to other designs in Table 1.

It is interesting to note that the pass gate MUX has higher performance than the tri-state MUX for CMOS implementations, but the opposite is true with TFET implementations because the CMOS pass gate benefits from conduction through a pair of PMOS and NMOS pass transistors. In the TFET circuit, however only one of the NTFET or PTFET pass transistors could be “ON” at any one time because the other transistor has a V_{DS} bias such that the TFET is “OFF”.

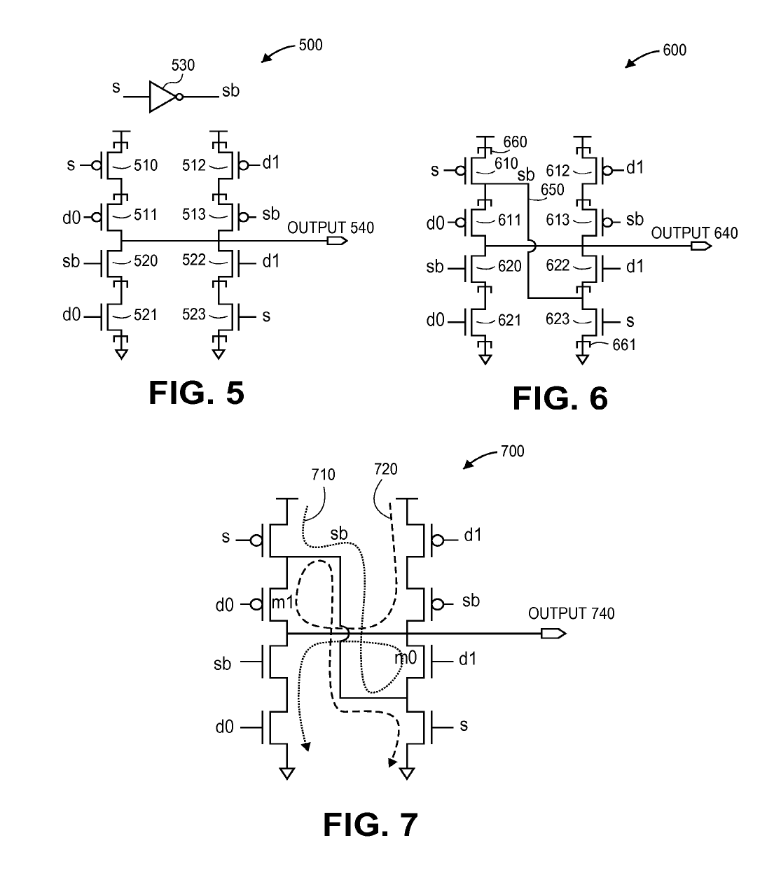

The structure and operation of the compact TFET MUX design can be explained by comparing the compact TFET MUX design to the tri-state MUX design. FIG. 5 illustrates a tri-state-like TFET multiplexor circuit in accordance with one embodiment. The order of serial transistors in the input stack have been switched from an arrangement that is illustrated in FIG. 4b having the TFETs with d0 and d1 inputs being nearest to the power supply and ground to an arrangement as illustrated in FIG. 5. However, logic functionality is still equivalent between FIGS. 4b and 5. Note that the circuit 500 includes an inverter 530 that generates an inverted select signal “sb” from the select signal “s”. The circuit 500 includes PTFET devices 510-513, NTFET devices 520-523, an inverter 530, and an output 540. In this embodiment, the MUX logic gate shown as circuit 500 has 10 transistors. With TFETs, this inverter can be removed as the inverted select signal can be generated within the core of the MUX cell itself.

FIG. 6 illustrates a multiplexor circuit having TFET devices in accordance with one embodiment. An additional connection 650 is needed as shown in FIG. 6 if the inverter 530 in FIG. 5, that includes two transistors, is removed. The circuit 600 includes PTFET devices 610-613, NTFET devices 620-623, and an output 640. A source terminal 660 of PTFET 610 is coupled to a supply voltage while a source terminal 661 of NTFET 623 is coupled to a ground reference terminal (ground voltage). The source terminal 660 receives the supply voltage while the source terminal 661 receives the ground voltage.

The orientation of the source and the drain terminals of the TFET device is very important because a circuit will not work properly with reversed source/drain orientation or with alternative devices (e.g., MOSFETs) with symmetric IV characteristics.

For example, FIG. 7 illustrates a multiplexor circuit based on FIG. 6 but having MOSFET devices. The circuit 700 includes p-type and n-type MOSFET devices and an output 740. The circuit 700 illustrates the problems associated with a CMOS compact MUX circuit. The transistor labeled m0 would allow a short circuit current between V_{DD} and a ground reference terminal for some input combinations. This path is shown by a dotted line 710. The transistor m0 would have a large V_{DS} and V_{GS} (e.g., V_{DS}=311 mV, V_{GS}=419 mV) so there would be a static current of 4.32 uA for this example. The transistor labeled m1 would also allow a short circuit current between V_{DD} and a ground reference terminal for some input combinations. This path is shown by a dotted line 720. The transistor m1 would have a large V_{DS} and V_{GS} so there would be static current of 4.32 uA for this example.

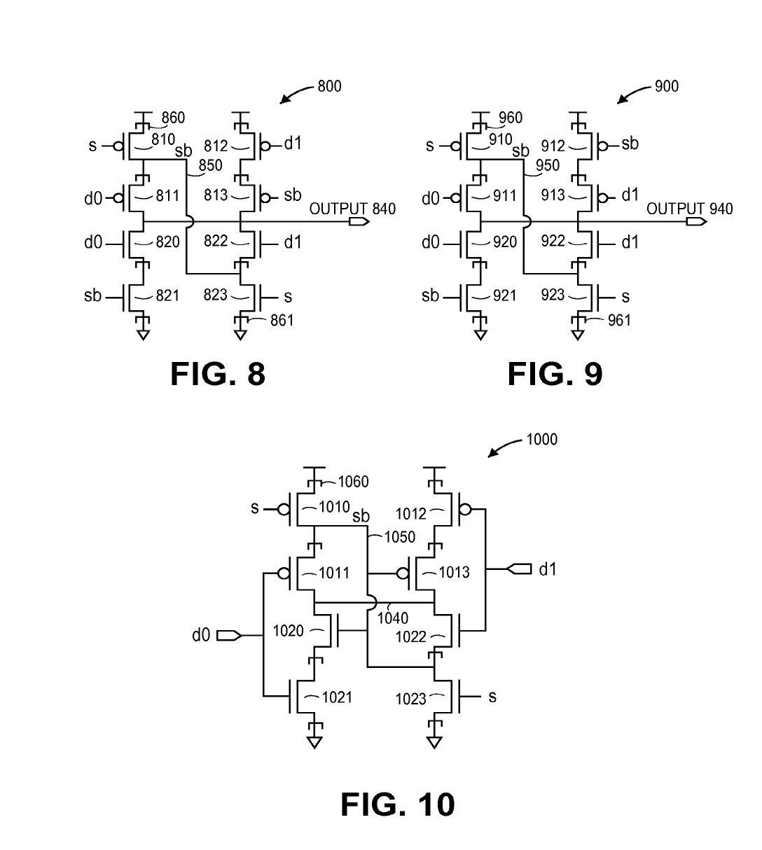

However, with TFET devices for the circuit 700, the V_{DS} of the NTFET (m0 transistor) would be negative so conduction would be minimal. A number of variants of this circuit are possible and a few examples are shown in FIGS. 8 and 9.

FIG. 8 illustrates a multiplexor circuit having TFET devices in accordance with one embodiment. The circuit 800 includes PTFET devices 810-813, NTFET devices 820-823, a connection 850 between a drain terminal of PTFET 810 and a drain terminal of NTFET 823, and an output 840. A source terminal 860 of PTFET 810 is coupled to a supply voltage while a source terminal 861 of NTFET 823 is coupled to a ground reference terminal (ground voltage). The source terminal 860 receives the supply voltage while the source terminal 861 receives the ground voltage.

FIG. 9 illustrates a multiplexor circuit having TFET devices in accordance with one embodiment. The circuit 900 includes PTFET devices 910-913, NTFET devices 920-923, a connection 950 between a drain terminal of PTFET 910 and a drain terminal of NTFET 923, and an output 940. A source terminal 960 of PTFET 910 is coupled to a supply voltage while a source terminal 961 of NTFET 823 is coupled to a ground reference terminal. The source terminal 960 receives the supply voltage while the source terminal 961 receives the ground voltage.

The transistors gated by “s” must be attached to the voltage supply or ground reference terminal to properly drive the inverted select signal “sb” but the serial arrangements of transistors gated by “d1”, “d0”, and “sb” can be in any order. The arrangement that yields fastest worst-case performance is shown in FIG. 10.

FIG. 10 illustrates a multiplexor circuit having TFET devices in accordance with one embodiment. The circuit 1000 includes PTFET devices 1010-1013, NTFET devices 1020-1023, a connection 1050 between a drain terminal of PTFET 1010 and a drain terminal of NTFET 1023, and an output terminal 1040. A source terminal 1060 of PTFET 1010 is coupled to a supply voltage while a source terminal 1061 of NTFET 1023 is coupled to a ground reference terminal.

In certain embodiments, the series arrangement of the TFET with “sb” as an input is designed closest to the output node because timing arcs originating with a “select” signal transition are most often the slowest as a transition of “s” must first switch “sb” before the output can switch, i.e., this arrangement enables the output delay from “sb” switching to have the minimum delay impact on the output switching.

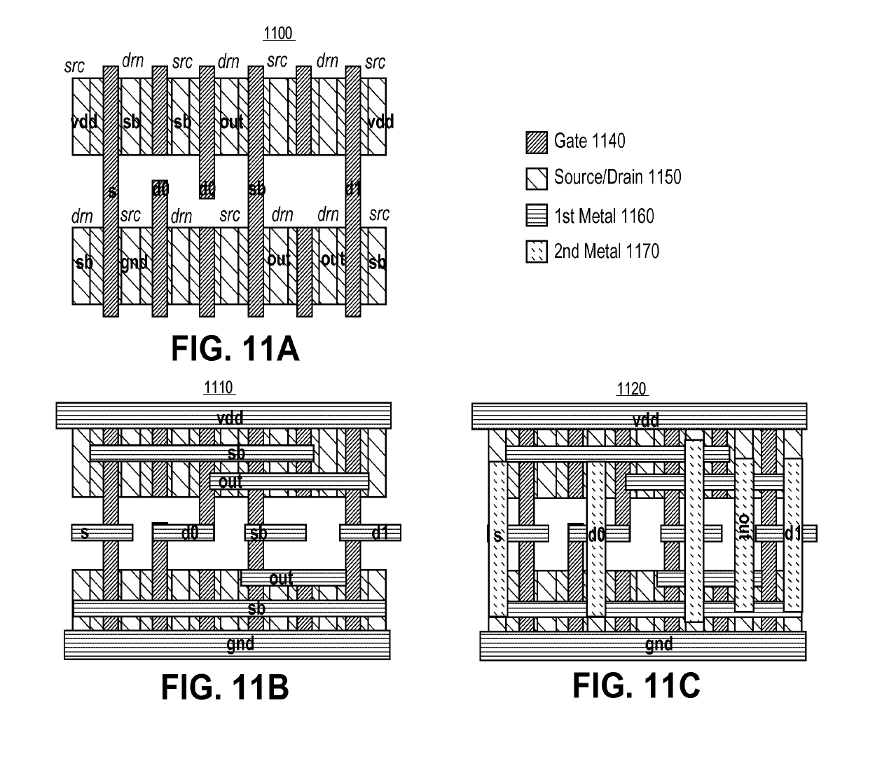

Exemplary layouts of a TFET MUX circuit are illustrated in FIGS. 11A-11C respectively in accordance with one particular embodiment. The layouts 1100, 1110, and 1120 illustrate exemplary layouts for the input data signals (“d0”, “d1”), select signals (“s”, “sb”), an output signal, a supply voltage (Vdd), and a ground reference terminal (gnd). These exemplary layouts also include a gate layer 1140, a source/drain layer 1150, a first metal layer 1160, and a second metal layer 1170.

In one embodiment, a p-type TFET can be designed with Si, Ge, Sn or any alloy of these materials in the source region and Si, Ge, Sn or any alloy of these materials in the active region including channel regions under the gate regions and also drain regions. In an embodiment, a TFET can be designed with In, Ga, Al, As, Sb, P, N or any alloy of these materials in the source region and In, Ga, Al, As, Sb, P, N or any alloy of these materials in the active region including channel regions under the gate regions and also drain regions. Including contacts, the TFET device can be designed as small as a counterpart MOSFET device.

In the above described embodiments, whether formed on virtual substrate layers or on bulk substrates, an underlying substrate used for TFET device manufacture may be composed of a semiconductor material that can withstand a manufacturing process. In an embodiment, the substrate is a bulk substrate, such as a P-type silicon substrate as is commonly used in the semiconductor industry. In an embodiment, substrate is composed of a crystalline silicon, silicon/germanium or germanium layer doped with a charge carrier, such as but not limited to phosphorus, arsenic, boron or a combination thereof. In another embodiment, the substrate is composed of an epitaxial layer grown atop a distinct crystalline substrate, e.g. a silicon epitaxial layer grown atop a boron-doped bulk silicon mono-crystalline substrate.

The substrate may instead include an insulating layer formed in between a bulk crystal substrate and an epitaxial layer to form, for example, a silicon-on-insulator substrate. In an embodiment, the insulating layer is composed of a material such as, but not limited to, silicon dioxide, silicon nitride, silicon oxy-nitride or a high-k dielectric layer. The substrate may alternatively be composed of a group III-V material. In an embodiment, the substrate is composed of a III-V material such as, but not limited to, gallium nitride, gallium phosphide, gallium arsenide, indium phosphide, indium antimonide, indium gallium arsenide, aluminum gallium arsenide, indium gallium phosphide, or a combination thereof. In another embodiment, the substrate is composed of a III-V material and charge-carrier dopant impurity atoms such as, but not limited to, carbon, silicon, germanium, oxygen, sulfur, selenium or tellurium.

In the above embodiments, TFET devices include source drain regions that may be doped with charge carrier impurity atoms. In an embodiment, the group IV material source and/or drain regions include N-type dopants such as, but not limited to phosphorous or arsenic. In another embodiment, the group IV material source and/or drain regions include P-type dopants such as, but not limited to boron.

In the above embodiments, although not always shown, it is to be understood that the TFETs include gate stacks with a gate dielectric layer and a gate electrode layer. In an embodiment, the gate electrode of gate electrode stack is composed of a metal gate and the gate dielectric layer is composed of a high-K material. For example, in one embodiment, the gate dielectric layer is composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, aluminium oxide, lead scandium tantalum oxide, lead zinc niobate, or a combination thereof. In an embodiment, the gate dielectric layer is composed of a top high-k portion and a lower portion composed of an oxide of a semiconductor material. In one embodiment, the gate dielectric layer is composed of a top portion of hafnium oxide and a bottom portion of silicon dioxide or silicon oxy-nitride.

In an embodiment, the gate electrode is composed of a metal layer such as, but not limited to, metal nitrides, metal carbides, metal silicides, metal aluminides, hafnium, zirconium, titanium, tantalum, aluminum, ruthenium, palladium, platinum, cobalt, nickel or conductive metal oxides. In a specific embodiment, the gate electrode is composed of a non-workfunction-setting fill material formed above a metal workfunction-setting layer. In an embodiment, the gate electrode is composed of a P-type or N-type material. The gate electrode stack may also include dielectric spacers.

The TFET semiconductor devices described above cover both planar and non-planar devices, including gate-all-around devices. Thus, more generally, the semiconductor devices may be a semiconductor device incorporating a gate, a channel region and a pair of source/drain regions. Furthermore, additional interconnect wiring may be fabricated in order to integrate such devices into an integrated circuit.

Generally, one or more embodiments described herein are targeted at tunneling field effect transistors (TFETs) for multiplexor circuits. Group IV or III-V active layers for such devices may be formed by techniques such as, but not limited to, chemical vapor deposition (CVD) or molecular beam epitaxy (MBE), or other like processes.

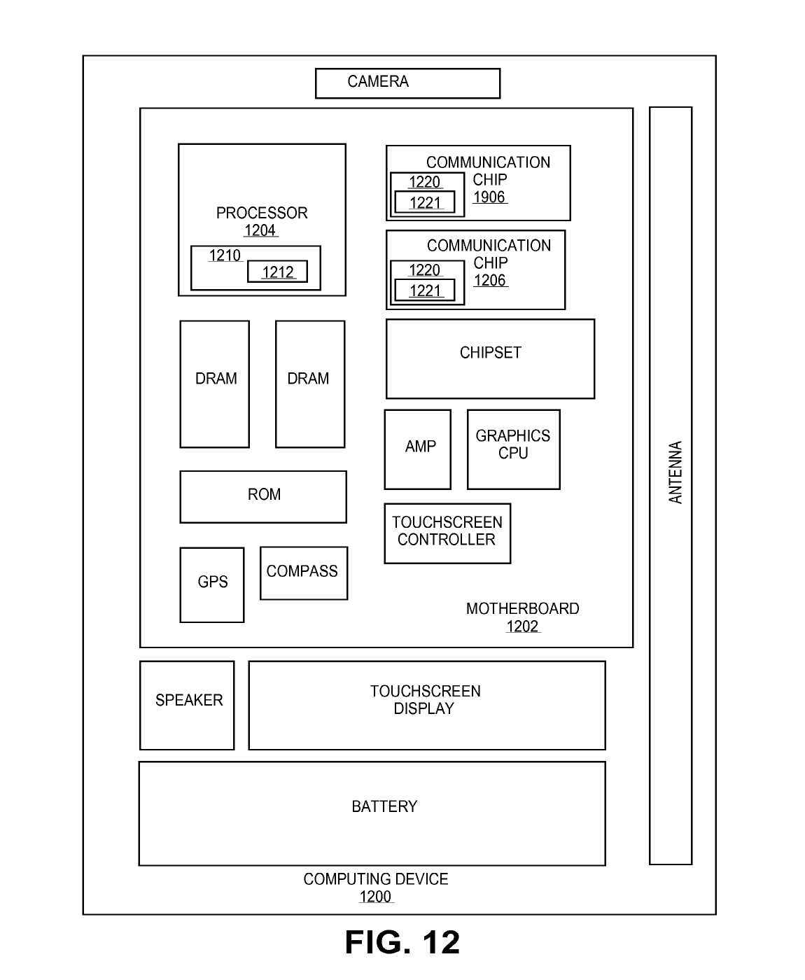

FIG. 12 illustrates a computing device 1200 in accordance with one implementation of the invention. The computing device 1200 houses a board 1202. The board 1202 may include a number of components, including but not limited to a processor 1204 and at least one communication chip 1206. The processor 1204 is physically and electrically coupled to the board 1202. In some implementations the at least one communication chip 1206 is also physically and electrically coupled to the board 1202. In further implementations, the communication chip 1206 is part of the processor 1204.

Depending on its applications, computing device 1200 may include other components that may or may not be physically and electrically coupled to the board 1202. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 1206 enables wireless communications for the transfer of data to and from the computing device 1200. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1206 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1200 may include a plurality of communication chips 1206. For instance, a first communication chip 1206 may be dedicated to shorter range wireless communications such as Wi-Fi and Bluetooth and a second communication chip 1206 may be dedicated to longer range wireless communications such as GPS, EDGE, GPRS, CDMA, WiMAX, LTE, Ev-DO, and others.

The processor 1204 of the computing device 1200 includes an integrated circuit die 1210 packaged within the processor 1204. In some implementations of the invention, the integrated circuit die of the processor includes one or more multiplexor circuits 1212 having tunneling field effect transistors (TFETs) built in accordance with implementations of the invention. The term “processor” may refer to any device or portion of a device that processes electronic data from registers and/or memory to transform that electronic data into other electronic data that may be stored in registers and/or memory.

The communication chip 1206 also includes an integrated circuit die 1220 packaged within the communication chip 1206. In accordance with another implementation of the invention, the integrated circuit die of the communication chip includes one or more multiplexor circuits 1921 having tunneling field effect transistors (TFETs) built and arranged in accordance with implementations of the invention.

In further implementations, another component housed within the computing device 1200 may contain an integrated circuit die that includes one or more multiplexor circuits having tunneling field effect transistors (TFETs) built and arranged in accordance with implementations of the invention.

In various implementations, the computing device 1200 may be a laptop, a netbook, a notebook, an ultrabook, a smartphone, a tablet, a personal digital assistant (PDA), an ultra mobile PC, a mobile phone, a desktop computer, a server, and High Performance Computer (HPC), a printer, a scanner, a monitor, a set-top box, an entertainment control unit, a digital camera, a portable music player, or a digital video recorder. In further implementations, the computing device 1200 may be any other electronic device that processes data.

Thus, embodiments of the present invention include multiplexor circuits having tunneling field effect transistors (TFETs).

In an embodiment, a multiplexor circuit (e.g., circuit 300, circuit 400, circuit 450, circuit 500, circuit 600, circuit 800, circuit 900, circuit 1000) includes a first set of tunneling field effect transistor (TFET) devices that are coupled to each other. The TFET devices receive a first data input signal, a first select signal, and a second select signal. A second set of TFET devices are coupled to each other and receive a second data input signal, the first select signal, and the second select signal. An output terminal is coupled to the first and second set of TFETs. The output terminal generates an output signal of the multiplexor circuit.

In one embodiment, the first set of TFET devices is coupled to the second set of TFET devices with a connection that provides the second select signal.

In one embodiment, the first set of TFET devices includes a TFET having a source terminal and a gate terminal to receive the first select signal. The source terminal receives a supply or ground voltage.

In an embodiment, the TFET devices of the first set of TFET devices are serially connected to each other (i.e., the source and drain terminals are serially connected to each other) and the TFET devices of the second set are serially connected to each other (i.e., the source terminal of one TFET device is serially connect to the drain terminals of another TFET). Each TFET of the first set of TFET devices can receive one of the first data input signal, the first select signal, and the second select signal respectively.

In one embodiment, the first set of TFET devices includes two n-type TFETs and two p-type TFETs. The second set of TFET devices includes two n-type TFETs and two p-type TFETs.

In an embodiment, each TFET of the second set of TFET devices receives one of the second data input signal, the first select signal, and the second select signal respectively.

In one embodiment, the multiplexor circuit includes a maximum of eight TFET devices.

In one embodiment, the multiplexing circuit (e.g., circuit 450) includes the first set of TFET devices with two n-type TFET devices and two p-type TFET devices. A first p-type TFET device is coupled in series to a first n-type TFET device and a second p-type TFET device is coupled in parallel to a second n-type TFET device. The second set of TFET devices includes two n-type TFET devices and two p-type TFET devices with a first p-type TFET device coupled in series to a first n-type TFET device and a second p-type TFET device coupled in parallel to a second n-type TFET device. The output of the first n and p type TFETs connect to the common node of the parallel n and p TFETs.

In one embodiment, the multiplexing circuit (e.g., circuit 400) includes the first set of TFET devices with two n-type TFET devices coupled to each other and two p-type TFET devices coupled to each other. The second set of TFET devices includes two n-type TFET devices coupled to each other and two p-type TFET devices coupled to each other.

In one embodiment, a multiplexor circuit (e.g., circuit 300, circuit 400, circuit 450, circuit 500, circuit 600, circuit 800, circuit 900, circuit 1000) includes p-type tunneling field effect transistor (TFET) devices that receive a first data input signal, a second data input signal, a first select signal, and a second select signal. N-type tunneling field effect transistor (TFET) devices are coupled to the p-type TFET devices. The n-type TFET devices receive the first and second data input signals, the first select signal, and the second select signal. An output terminal is coupled to the n-type and p-type TFET devices to generate an output signal of the multiplexor circuit. At least one transistor of the p-type TFET devices is coupled to at least one transistor of the n-type TFET devices with a connection that provides the second select signal. The p-type TFET devices include a p-type TFET device having a source terminal that is coupled to a supply voltage and a gate terminal to receive the first select signal. The n-type TFET device includes a n-type TFET device having a source terminal that is coupled to a ground voltage and a gate terminal to receive the first select signal.

In one embodiment, a computing device (e.g., computing device 1200) includes memory to store electronic data and a processor that is coupled to the memory. The processor processes electronic data and includes an integrated circuit die having a multiplexor circuit. The multiplexor circuit (e.g., circuit 300, circuit 400, circuit 450, circuit 500, circuit 600, circuit 800, circuit 900, circuit 1000) includes a first set of tunneling field effect transistor (TFET) devices that are coupled to each other and receive a first data input signal, a first select signal, and a second select signal.

A second set of TFET devices is coupled to each other and receives a second data input signal, the first select signal, and the second select signal. An output terminal is coupled to the first and second set of TFET devices. The output terminal generates an output signal of the multiplexor circuit. The first set of TFET devices is coupled to the second set of TFET devices with a connection that provides the second select signal.

In one embodiment, the first set of TFET devices includes a TFET device having a source terminal and a gate terminal to receive the first select signal. The source terminal to receive a supply or ground voltage.

In one embodiment, the TFET devices of the first set of TFET devices are serially connected to each other (i.e., the source and drain terminals are serially connected to each other).

In one embodiment, the TFET devices of the second set of TFET devices are serially connected to each other (i.e., the source and drain terminals are serially connected to each other).

What is claimed is:

1. A multiplexor circuit, comprising:
a first set of tunneling field effect transistor (TFET) devices coupled to each other to receive a first data input signal, a first select signal, and a second select signal;
a second set of TFET devices coupled to each other to receive a second data input signal, the first select signal, and the second select signal; and
an output terminal coupled to the first and second set of TFETs, the output terminal to generate an output signal of the multiplexor circuit.

2. The multiplexor circuit of claim 1, wherein the first set of TFET devices is coupled to the second set of TFET devices with a connection that provides the second select signal.

3. The multiplexor circuit of claim 1, wherein the first set of TFET devices includes a TFET having a source terminal and a gate terminal to receive the first select signal, the source terminal to receive a supply or ground voltage.

4. The multiplexor circuit of claim 1, wherein the TFET devices of the first set of TFET devices are serially connected to each other.

5. The multiplexor circuit of claim 1, wherein each TFET of the first set of TFET devices to receive one of the first data input signal, the first select signal, and the second select signal.

6. The multiplexor circuit of claim 5, wherein the first set of TFET devices comprises two n-type TFETs and two p-type TFETs.

7. The multiplexor circuit of claim 1, wherein the TFET devices of the second set of TFET devices are serially connected to each other.

8. The multiplexor circuit of claim 7, wherein each TFET of the second set of TFET devices to receive one of the second data input signal, the first select signal, and the second select signal.

9. The multiplexor circuit of claim 8, wherein the second set of TFET devices comprises two n-type TFETs and two p-type TFETs.

10. The multiplexor circuit of claim 1, wherein the multiplexor circuit includes a maximum of eight TFET devices.

11. The multiplexor circuit of claim 1, wherein the first set of TFET devices comprises a first p-type TFET device coupled in series to a first n-type TFET device and a second p-type TFET device coupled in parallel to a second n-type TFET device.

12. The multiplexor circuit of claim 11, wherein the second set of TFET devices comprises a first p-type TFET device coupled in series to a first n-type TFET device and a second p-type TFET device coupled in parallel to a second n-type TFET device.

13. The multiplexor circuit of claim 1, wherein the first set of TFET devices comprises two n-type TFET devices coupled to each other and two p-type TFET devices coupled to each other.

14. The multiplexor circuit of claim 13, wherein the second set of TFET devices comprises two n-type TFET devices coupled to each other and two p-type TFET devices coupled to each other.

15. A multiplexor circuit, comprising:
p-type tunneling field effect transistor (TFET) devices to receive a first data input signal, a second data input signal, a first select signal, and a second select signal;
n-type tunneling field effect transistor (TFET) devices coupled to the p-type TFET devices, the n-type TFET devices to receive the first data input signal, the second data input signal, the first select signal, and the second select signal; and
an output terminal coupled to the n-type and p-type TFET devices to generate an output signal of the multiplexor circuit.

16. The multiplexor circuit of claim 15, wherein at least one transistor of the p-type TFET devices is coupled to at least one transistor of the n-type TFET devices with a connection that provides the second select signal.

17. The multiplexor circuit of claim 15, wherein the p-type TFET devices includes a p-type TFET device having a source terminal that is coupled to a supply voltage and a gate terminal to receive the first select signal.

18. The multiplexor circuit of claim 15, wherein the n-type TFET devices include a n-type TFET device having a source terminal that is coupled to a ground voltage and a gate terminal to receive the first select signal.

19. A computing device, comprising:
memory to store electronic data; and
a processor coupled to the memory, the processor to process electronic data, the processor includes an integrated circuit die having a multiplexor circuit, the multiplexor circuit comprising:
a first set of tunneling field effect transistor (TFET) devices coupled to each other to receive a first data input signal, a first select signal, and a second select signal;
a second set of TFET devices coupled to each other to receive a second data input signal, the first select signal, and the second select signal; and
an output terminal coupled to the first and second set of TFET devices, the output terminal to generate an output signal of the multiplexor circuit.

20. The computing device of claim 19, wherein the first set of TFET devices is coupled to the second set of TFET devices with a connection that provides the second select signal.

21. The computing device of claim 19, wherein the first set of TFET devices includes a TFET device having a source terminal and a gate terminal to receive the first select signal, the source terminal to receive a supply or ground voltage.

22. The computing device of claim 19, wherein the TFET devices of the first set of TFET devices are serially connected to each other.

23. The computing device of claim 19, wherein the TFET devices of the second set of TFET devices are serially connected to each other.

24. The computing device of claim 19, wherein the second set of TFET devices includes a TFET device having a source terminal and a gate terminal to receive the first select signal, the source terminal to receive a supply or ground voltage.
